(19) United States
(12) Patent Application Publication
(10) Pub. No.: US 2026/0165118 A1
(43) Pub. Date: Jun. 11, 2026

(54) SEMICONDUCTOR DEVICE MODULE WITH STACKED INTERCONNECTIONS AND METHODS OF MANUFACTURE

(71) Applicant: SEMICONDUCTOR COMPONENTS INDUSTRIES, LLC, Scottsdale, AZ (US)

(72) Inventors: Seungwon IM, Bucheon (KR); Jonghwan BAEK, Gimpo-city (KR)

(73) Assignee: SEMICONDUCTOR COMPONENTS INDUSTRIES, LLC, Scottsdale, AZ (US)

(21) Appl. No.: 18/976,211

(22) Filed: Dec. 10, 2024

(51) Int. Cl. H01L 23/00; H01L 23/34; H01L 23/373; H01L 25/00; H01L 25/07

(52) U.S. Cl. CPC H10W 40/00; H10W 40/255; H10W 90/00; H10W 72/073; H10W 72/075; H10W 72/076; H10W 72/631; H10W 72/884; H10W 72/886; H10W 90/734; H10W 90/755; H10W 90/763

(57) ABSTRACT

In a general aspect, a semiconductor device assembly includes a substrate, a semiconductor die electrically coupled with the substrate, and a leadframe portion having an opening defined therethrough. The leadframe portion is coupled with the substrate such that the semiconductor die is disposed within the opening. The assembly further includes a conductive member having a first portion that is electrically coupled with a surface of the leadframe portion bordering the opening; and a second portion that is electrically coupled with the semiconductor die.

### SUMMARY

In a general aspect, a semiconductor device assembly includes a substrate, a semiconductor die electrically coupled with the substrate, and a leadframe portion having an opening defined therethrough. The leadframe portion is coupled with the substrate such that the semiconductor die is disposed within the opening. The assembly further includes a conductive member having a first portion that is electrically coupled with a surface of the leadframe portion bordering the opening; and a second portion that is electrically coupled with the semiconductor die.

In another general aspect, a semiconductor device assembly includes a substrate, a first semiconductor die, a second semiconductor die, a third semiconductor die and a fourth semiconductor die electrically coupled with the substrate. The assembly further includes a first leadframe portion having a first opening and a second opening defined therethrough. The first leadframe portion is coupled with the substrate such that the first semiconductor die is disposed within the first opening and the second semiconductor die is disposed within the second opening. The assembly further includes a first conductive member having a first portion electrically coupled with a surface of the first leadframe portion bordering the first opening and the second opening, a second portion electrically coupled with the first semiconductor die, and a third portion electrically coupled with the second semiconductor die. The assembly also includes a second leadframe portion having a third opening and a fourth opening defined therethrough. The second leadframe portion is coupled with the substrate such that the third semiconductor die is disposed within the third opening, and the fourth semiconductor die is disposed within the fourth opening. The assembly also includes a second conductive member having a first portion electrically coupled with a surface of the second leadframe portion bordering the third opening and the fourth opening, a second portion electrically coupled with the third semiconductor die, and a third portion electrically coupled with the fourth semiconductor die.

### BRIEF DESCRIPTION OF THE DRAWINGS

FIGS. 1A to 1C are diagrams illustrating, respectively, a top side view, a bottom side view, and a side view of an example semiconductor device assembly.

FIG. 2 is a diagram illustrating an example substrate assembly that can be included in the semiconductor device assembly of FIGS. 1A to 1C.

FIG. 3 is a diagram illustrating an example leadframe that can be included in the semiconductor device assembly of FIGS. 1A to 1C.

FIG. 4 is a diagram illustrating an example conductive member (conductive clip) that can be included in the semiconductor device assembly of FIGS. 1A to 1C.

FIG. 5 is a diagram illustrating the leadframe of FIG. 3 coupled (stacked) with the substrate assembly of FIG. 2.

FIG. 6A is a diagram illustrating the substrate assembly of FIG. 2, the leadframe of FIG. 3 and conductive clips of FIG. 4 in an example stacked arrangement that can be included in the semiconductor device assembly of FIGS. 1A to 1C.

FIG. 6B is a diagram illustrating a magnified view of a portion of the stacked arrangement of FIG. 6A.

FIG. 7 is a diagram illustrating an example of the stacked arrangement of FIGS. 6A and 6B after attaching wire bonds (bond wires).

FIG. 8 is a flowchart illustrating an example method for producing a semiconductor device assembly, such as the assembly of FIGS. 1A to 1C.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

This disclosure relates to packaged semiconductor device apparatuses, which can be referred to as modules, assemblies, semiconductor device modules, power semiconductor device modules, semiconductor device assemblies, electronic device assemblies, etc., as well as associated methods for producing such apparatuses. The approaches illustrated and described herein can be used to implement molded (e.g., transfer molded) semiconductor device modules that can overcome at least some of the drawbacks of prior modules. In some implementations, the described approaches can be used to implement a half-bridge power module, a full-bridge power module, a 3-phase half-bridge power module, a multi-phase half-bridge power module, etc., which can be used in automotive application, industrial applications, and/or consumer electronics applications.

One technical problem with prior power module implementations is an overall size of such modules (e.g., dimensions and/or mass), which can increase their cost, as well as the size and cost of associated components, such as cooling components (e.g., heat sinks, fluidic cooling jacket housings, etc.). One technical solution to the foregoing technical problem is to implement such power modules using stacked interconnections, such as a substrate, semiconductor die, leadframe components and one or conductive members (conductive clips) that are arranged, generally, in a vertical stack.

In some implementations in accordance with this technical solution, semiconductor die included in the module can be implemented using semiconductor materials that allow for higher operating power (e.g., operating current density and/or operating voltage) than prior implementations. For instance, semiconductor devices implemented using silicon carbide (SiC) can be used in place of semiconductor die implemented using silicon (Si). Such implementations, for a given power requirement or rating of a module, can allow for a reduction in a number of semiconductor die and/or reduced size of semiconductor die included in a semiconductor device assembly, which can facilitate additional module size reduction.

One technical benefit of the foregoing technical solution is, for a given power module configuration (e.g., a half-bridge circuit) with a given power rating, is a decrease in power module dimensions (e.g., x and y dimensions). For instance, in some implementations, power module dimensions can be decreased so as to achieve a 45% reduction in overall area of a semiconductor device assembly (e.g., power module, package, etc.). Accordingly, cost of a power module can be reduced, and size (dimensions, mass) and cost of associated components, such as cooling mechanisms, can also be achieved.

Another benefit of the foregoing of the foregoing technical solution is a reduction in material usage and/or elimination of one or components. For instance usage of copper, ceramic, semiconductor materials, etc., can be reduced as a result of reduced module size. As compared to prior implementations, some materials or components, such a printed circuit boards used for signal routing, can be eliminated. Such reductions in, or elimination of material usage can reduce cost, size and/or mass of a semiconductor device assembly (module, package, etc.) as compared to prior implementations.

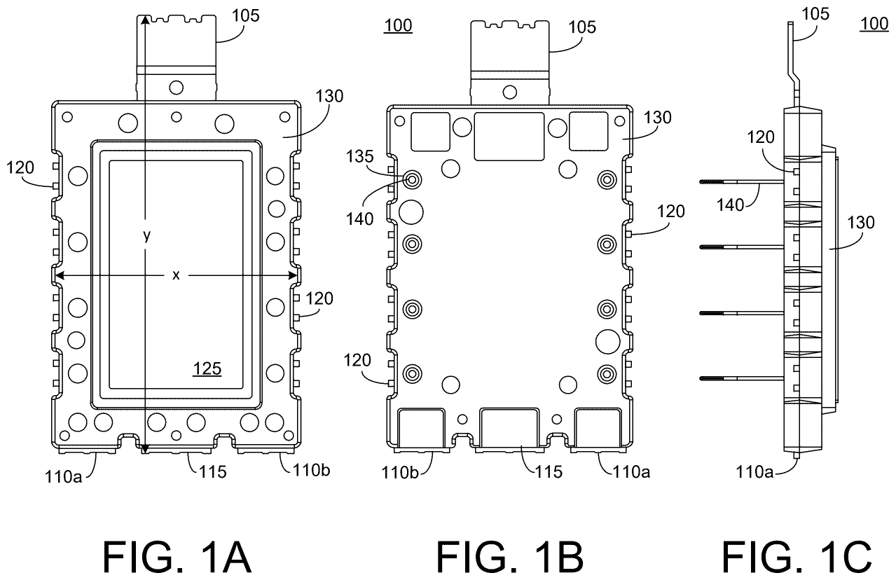

FIGS. 1A to 1C are diagrams illustrating, respectively, a top view, a bottom view, and a side view of an example semiconductor device assembly 100. As shown in the top view of FIG. 1A, the semiconductor device assembly 100 includes a terminal 105, a terminal 110a, a terminal 110b, a terminal 115 and a plurality of terminals 120, which can be included in a leadframe of the semiconductor device assembly 100, such as the example leadframe 300 shown in FIG. 3. As described in further detail below, a leadframe of the semiconductor device assembly 100 can include a plurality of leadframe portions that respectively include the terminal 105, the terminal 110a, the terminal 110b, the terminal 115 and the plurality of terminals 120.

Although referred to, by way of example, as a leadframe in at least some portions of this detailed description, a leadframe can include any type of conductive portion of a package or semiconductor device assembly (e.g., conductive portion, conductive terminal, etc.) that can provide an external connection point from an assembly to components, such as semiconductor die, within (e.g., encapsulated in) the assembly. Accordingly, the leadframe can be referred to as a conductive portion of the package. Furthermore, the semiconductor device assemblies described herein, as noted above, can include a plurality of terminals, such those noted above. The plurality of terminals can be power terminals, input signal terminals, output signal terminals, signal pins, and so forth. In some implementations, the plurality of terminals can be included in, coupled with, and/or attached to a leadframe, such as described herein.

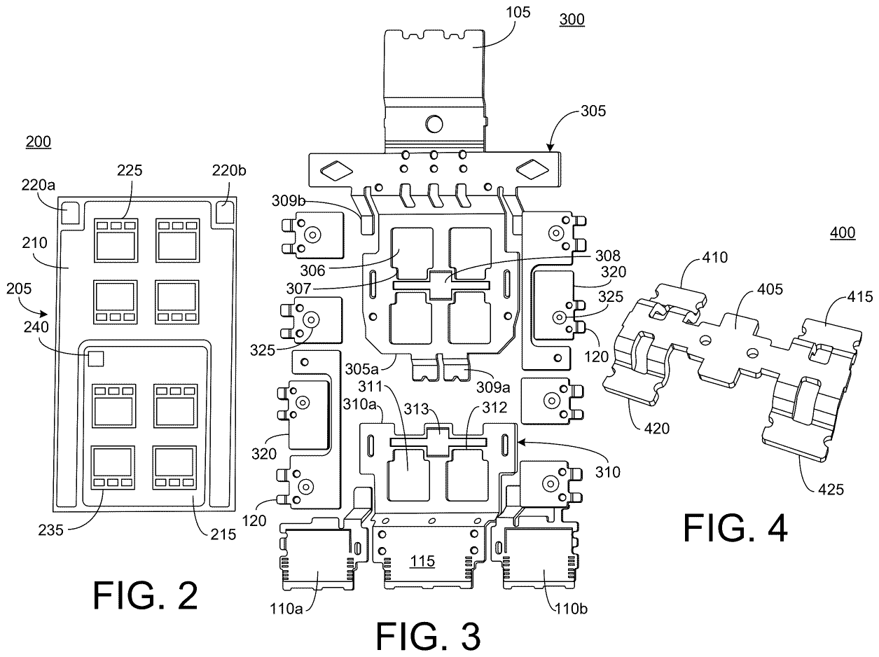

In some implementations, one or more portions of a leadframe can be coupled to a pad (e.g., a bond pad) on at least a portion of a substrate, such as a direct-bonded metal (DBM) substrate (e.g., the substrate described below with respect to, at least, FIG. 2). Briefly, however, as also shown in FIG. 1A, the semiconductor device assembly 100 includes a metal layer 125 that is exposed through an encapsulant material, such a molding compound 130. In some implementations, the metal layer 125 can be included in a substrate (e.g., a DBM substrate or other substrate) and used for attachment of the semiconductor device assembly 100 with a heat dissipation component, such as heat sink or fluidic cooling jacket.

In some implementations, the molding compound 130 (e.g., molding material or compound, an encapsulation material) can be, or can include a non-conducting layer/material. In some implementations, the molding compound 130 is a non-conducting material, such as an epoxy, which can be formed (applied, etc.) using a transfer molding process or a compression molding process in conjunction with corresponding tooling, e.g., a molding jig. In some implementations, the molding compound can include a separate plastic housing that is included in the semiconductor device assembly.

As shown in FIG. 1A, the semiconductor device assembly 100 has a width dimension of x (e.g., a lateral or horizontal dimension) and a height dimension of y (e.g., a longitudinal or vertical dimension). In some implementations, as compared to prior assemblies with similar operating characteristics, the width and height dimensions, x and y, can be respectively reduced on the order of 20-35%, with an overall area of the semiconductor device assembly 100 being reduced on the order of 45 to 50% as compared to prior implementations. Such reductions in dimensions and areas can achieve the technical benefits described above.

FIG. 1B illustrates a bottom view of the semiconductor device assembly 100, which is opposite the view shown in FIG. 1A, As shown in FIG. 1B, the semiconductor device assembly 100 includes a plurality of signal pin sockets 135 that are exposed through the molding compound 130, and a plurality of signal pins 140 that are respectively disposed in the plurality of signal pin sockets 135. The signal pins 140 can be respectively included in terminals of the semiconductor device assembly 100.

In some implementations, such as in the examples described herein, the plurality of signal pin sockets 135 can be cylindrical features (or features having other shapes) that are included in a leadframe, where openings in the cylindrical features are configured to receive the signal pins 140. In some implementations, the signal pins 140 can be held in the plurality of signal pin sockets 135 by frictional forces and/or with a conductive adhesive, such as solder, a conductive epoxy, etc. In some implementations, the signal pins 140 and the plurality of signal pin sockets 135 can included in, e.g., provide electrical connections to, respective terminals of the leadframe of the semiconductor device assembly 100, such as the terminals described above.

FIG. 1C illustrates a side view of the semiconductor device assembly 100, e.g., from a right side of the semiconductor device assembly 100 in the view of FIG. 1B. As shown in FIG. 1C, the signal pins 140 extend out of, and away from the molding compound 130 of the semiconductor device assembly 100. In some implementations, the portions of the signals pins 140 extended outside the molding compound 130 can be inserted in a socket (or sockets) of a corresponding electrical system, such as an inverter system for an electric or hybrid vehicle, or other electrical system. In some implementations, the signal pins 140 (as well as the terminal 105, the terminal 110a, the terminal 110b, and the terminal 115 can be plated, or partially plated, e.g., with a solder plating. Such plating can facilitate electrical attachment of the semiconductor device assembly 100 in a corresponding electrical system, e.g., using a solder reflow process.

FIG. 2 is a diagram illustrating an example substrate assembly 200, which can be included in the semiconductor device assembly 100 of FIGS. 1A to 1C. That is, in some implementations the substrate assembly 200 can be a sub-assembly of the semiconductor device assembly 100. As shown in FIG. 2, the substrate assembly 200 includes a substrate 205, which can be a DBM substrate. In some implementations, a direct bonded metal (DBM) substrate can include an insulating layer disposed between a first metal layer and a second metal layer. The insulating layer can be, for example, a ceramic layer. In some implementations, the insulating layer can be, or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process and/or a lamination process.

In some implementations, the first metal layer and/or the second metal layer of the DBM substrate can be, or can function as a heat sink. In some implementations, the first metal layer and/or the second metal layer (such as the metal layer 125 of the semiconductor device assembly 100) can be coupled to a heat sink or other heat dissipation component. In some implementations, at least a portion of one or more of the first metal layer or the second metal layer can be exposed through a molding material, such as shown in FIG. 1A.

In some implementations, the first metal layer and/or the second metal layer of the DBM substrate can be or can include a patterned metal layer including one or more electrically conductive traces, such as shown in FIG. 2. In some implementations, the first metal layer and/or the second metal layer can be, or can include a patterned layer configured to form one or more electrical circuits, one or more patterned metal layers or metal layer portions, one or more conductive blind and/or through vias, and/or so forth.

In some implementations, the DBM substrate can be, or can include a direct bonded copper (DBC) substrate (e.g., a DBM with copper metal layers). In some implementations, such as in DBC substrate implementations, the first metal layer and/or the second metal layer is a copper layer.

For instance, in the example of FIG. 2, the substrate 205 includes a metal layer 210 (e.g., a first patterned metal layer or metal layer portion), a metal layer 215 (e.g., a second patterned metal layer or metal layer portion), and metal layers 220a and 220b (e.g., third and fourth patterned metal layers or metal layer portions). In this example, the metal layer 125 shown in FIG. 1A can be disposed on an opposite side of the substrate 205 as shown in the view of FIG. 2 (e.g., on an opposite side of an insulating layer of the substrate 205).

As shown in FIG. 2, the substrate assembly 200 includes a plurality of semiconductor die 225 that are coupled (electrically coupled, physically coupled) with the metal layer 210. The substrate assembly 200 also includes a plurality of semiconductor die 235 that are coupled (electrically coupled, physically coupled) with the metal layer 215. In some implementations, the plurality of semiconductor die 225 and the plurality of semiconductor die 235 can be coupled with their respective metal layers using a number of different processes, such as soldering processes, or sintering processes.

In some implementations, soldering can be, or can include a process of joining two surfaces (e.g., metal surfaces and semiconductor surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal or metal-to-semiconductor type bonding materials.

In some implementations, a coupling of components can be performed using, for example, a solder process, a sintering process (e.g., a silver sintering process, a copper sintering process), and/or other metal-to-metal or metal-to-semiconductor bonding processes.

By way of example, and for purposes of illustration, the plurality of semiconductor die 225 can include respective SiC power transistors (e.g., MOSFET transistors) that are used to implement a high-side switch of a half-bridge circuit (with the respective transistors being connected in parallel). Also in this example, the plurality of semiconductor die 235 can include respective SiC power transistors (e.g., MOSFET transistors) that are used to implement a low-side switch of a half-bridge circuit (with the respective transistors being connected in parallel). In some implementations, other circuits can be implemented and/or combinations of transistors can be included in the substrate assembly 200.

For instance, in some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRD), a diode, and/or so forth. In some implementations, one or more semiconductor die can be (e.g., can be a portion of), or can include a component for an electrical vehicle (EV).

More than one semiconductor die can be included in the implementations described herein, as in the substrate assembly 200 of FIG. 2. In some implementations, different semiconductor die (when more than one semiconductor die is included) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT or MOSFET can be fabricated using a SiC substrate, while a controller can be fabricated using a silicon substrate.

In example implementations, a first semiconductor die can be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may also be connected to leadframe posts, leadframe portions, and/or leadframe terminals by electrical connections such as wire bonds or conductive clips.

As shown in FIG. 2, the substrate assembly 200 further includes a temperature sensing device 240 (e.g., a thermistor, a positive temperature coefficient (PTC) sensor, etc.) that is coupled with the metal layer 215. In some implementations, the temperature sensing device 240 could be included in a different location on the substrate 205, e.g., on the metal layer 210, etc.

FIG. 3 is a diagram illustrating an example leadframe 300 that can be included in implementations of the semiconductor device assembly 100 of FIGS. 1A to 1C. The view in FIG. 3, as well as the views in FIGS. 4, 5, 6A and 6B are shown as perspective views. In some implementations, the leadframe 300 can be implemented in the semiconductor device assembly 100 in conjunction with the substrate assembly 200 of FIG. 2 and the conductive member (conductive clip) of FIG. 4. In some implementations, the leadframe 300 can be implemented in a semiconductor device assembly in other configurations, such as with substrate assemblies having different arrangements, and/or different semiconductor die sub-assemblies. In FIG. 3, the terminals of the semiconductor device assembly 100 described with respect to FIGS. 1A to 1C are referenced with their same reference 100-series labels in the leadframe 300.

As shown in FIG. 3, the leadframe 300 includes a leadframe portion 305, a leadframe portion 310, the terminal 110a, the terminal 110b, the terminal 115, and a plurality of terminals 320 (not all referenced in the FIG. 3), which include the terminals 120 of FIGS. 1A to 1C. In this example, the terminal 105 is included in the leadframe portion 305 and the terminal 115 is included in the leadframe portion 310. While not specifically shown in FIG. 3, in some implementations, the various components of the leadframe 300 can be connected using tie bars, where the tie bars are removed as part of trim operation performed during a manufacturing processes used to produce a semiconductor device assembly, e.g., the semiconductor device assembly 100. For instance, such tie bars can maintain a relative arrangement of the components of the leadframe 300 during the assembly manufacturing process.

As shown in FIG. 3, the leadframe portion 305 includes a sub-portion 305a that includes a plurality of openings 306 that are defined therethrough. That is, the plurality of openings 306 are openings through the sub-portion 305a of the leadframe 300. In some implementations, the plurality of openings 306 (and other features of the leadframe 300 described herein) can be formed using one or more metal working processes, such as metal rolling, stamping, casting, milling, drilling, etc. The plurality of openings 306 also include respective alignment features 307. In this example, the respective alignment features 307 are channels or grooves that are defined in respective sidewalls of the plurality of openings 306.

The sub-portion 305a also includes a surface 308 that includes an upper surface of sidewalls defining the plurality of openings 306, where respective portions of the surface 308 border (are adjacent to) the plurality of openings 306. In other words, at least a portion of the surface 308 includes upper surfaces of walls (bars, partitions, etc.) of the sub-portion 305a that define the plurality of openings 306. In some implementations, the respective alignment features 307 and/or the surface 308 can facilitate self-alignment of a conductive member, such as the conductive clip shown in FIG. 4. In some implementations, the surface 308 can include a groove or a protrusion for contacting the conductive member and/or facilitating, at least in part, self-alignment of a conductive member when coupled with the leadframe portion 305 of the leadframe 300. For instance, such self-alignment can align respective portions of the conductive member with contact pads of corresponding semiconductor die, such as in example implementations described herein. In this example, the sub-portion 305a includes contact tabs 309a and contact tabs 309b that can be used to electrically couple the leadframe 300 (e.g., the sub-portion 305a) with metal layers of the substrate 205. While not specifically references in FIG. 3, other portions of the leadframe 300 include such contact tabs.

As further shown in FIG. 3, the leadframe portion 310 includes a sub-portion 310a that includes a plurality of openings 311 that are defined therethrough. That is, as with the plurality of openings 306, the plurality of openings 311 are openings through the sub-portion 310a of the leadframe 300. As with the plurality of openings 306, the plurality of openings 311 also include respective alignment features 312. The sub-portion 310a of the leadframe 300 also includes a surface 313 which is similar to the surface 308 of the sub-portion 305a, and can include similar features and aspects (e.g., for self-alignment of a conductive member).

As shown in FIG. 3, the leadframe 300 also includes a plurality of signal pin sockets 325 that are respectively included in terminals of the leadframe 300. In this example, the plurality of signal pin sockets 325 include respective cylindrical features that define openings that are configured to receive respective signal pins, such as the signal pins 140 of the semiconductor device assembly 100.

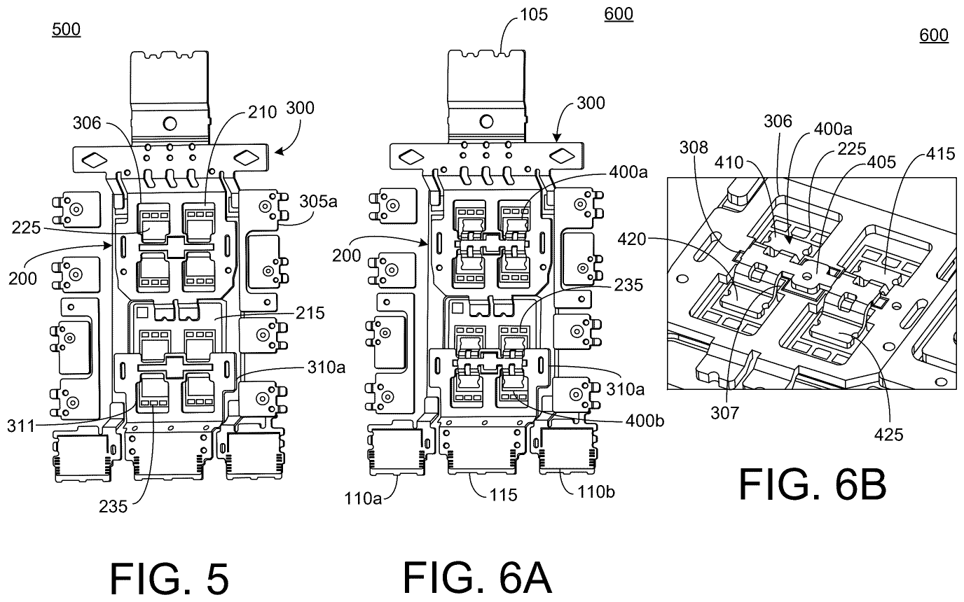

FIG. 4 is a diagram illustrating an example conductive member (a conductive clip 400) that can be included in the semiconductor device assembly of FIGS. 1A to 1C. In this example, the conductive clip 400 can be used in conjunction with the substrate assembly 200 and the leadframe 300 in implementations of the semiconductor device assembly 100, such as described below with respect to, at least FIGS. 5, 6A and 6B. As shown in FIG. 4, the conductive clip 400 includes a portion 405, a portion 410, a portion 415, a portion 420 and a portion 425. As with the leadframe 300, the conductive clip 400 can be formed using one or more metal working process. In some implementations, the conductive clip 400 (as well as the leadframe 300) can include copper, an alloy of copper, and/or other metal or electrically conductive materials.

In example implementations described herein, the portion 405 can contact, and be electrically coupled with the leadframe 300, e.g., the surface 308 of the sub-portion 305a, or the surface 313 of the sub-portion 310a of the leadframe 300. In such example implementations, the portion 410, the portion 415, the portion 420, and the portion 425 can contact, and be electrically coupled with contact pads of semiconductor die of the semiconductor device assembly 100. For instance, the portions 410 to 425 can respectively contact semiconductor die of the plurality of semiconductor die 225 or the plurality of semiconductor die 235. In some implementations, alignment features of the leadframe 300, such as those described herein, can facilitate self-alignment of the portions 410 to 425 of the conductive clip 400 with corresponding contact pads of semiconductor die included in a semiconductor device assembly.

In some implementations, the substrate assembly 200, the leadframe 300 and at least one conductive clip 400 can be used to implement the semiconductor device assembly 100. For instance, the substrate assembly 200, the leadframe 300 and the conductive clip(s) 400 can be implemented in a stacked arrangement in the semiconductor device assembly 100, such as illustrated and described with respect to FIGS. 5, 6A and 6B below. Such a stacked arrangement can be referred to herein as a vertical stack, or described as an arrangement where the substrate assembly 200, the leadframe 300 and the conductive clip(s) 400 are vertically stacked.

FIG. 5 is a diagram illustrating a sub-assembly 500 (e.g., of the semiconductor device assembly 100) including the leadframe of FIG. 3 coupled with the substrate assembly 200 of FIG. 2. As shown in FIG. 5, the leadframe 300 is coupled (stacked, vertically stacked) with the substrate assembly 200. In some implementations, the leadframe 300 (portions of the leadframe, such as the contact tabs 309a) can be electrically coupled with the leadframe using approaches described herein, such as soldering and/or sintering. In addition to electrically coupling one or more parts of the leadframe 300 with the substrate assembly 200, one or more other parts of the leadframe 300 may be coupled with the substrate assembly 200 without establishing an electrical connection to the substrate assembly 200.

For instance, in an example implementation of the semiconductor device assembly 100 including a half-bridge circuit, such as described herein, portions of the leadframe 300 disposed above (stacked above) particular metal layers of the substrate 205 may not be electrically coupled with those metal layers. For instance, as shown in FIG. 5, the sub-portion 305a of the leadframe 300 is disposed above the metal layer 210 of the substrate 205. However, in this example (e.g., a half-bridge circuit) the sub-portion 305a is not electrically coupled with the metal layer 210, but is instead electrically coupled with the metal layer 215 via contact tabs 309a.

In some implementations, the sub-portion 305a may be physically separated from the metal layer 210 to prevent an electrical connection therebetween. In some implementations, non-conductive posts and/or non-conductive adhesive can be used to establish this separation while physically coupling the leadframe 300 with the substrate assembly 200. In some implementations, a non-conductive film can be selectively applied (e.g., by photolithographic patterning) to prevent electrical coupling between the sub-portion 305a and the metal layer 210. Further in the half-bridge circuit example, as also shown in FIG. 5, the sub-portion 310a of the leadframe 300 is disposed above the metal layer 215 of the substrate 205. However, in this example the sub-portion 310a is not electrically coupled with the metal layer 215 and, in fact, is not electrically coupled (directly electrically coupled) with the substrate 205. Similar approaches as discussed with respect to the sub-portion 305a and the metal layer 210 can be used to prevent electrical connection between the sub-portion 310a and the metal layer 215.

As shown in FIG. 5, the plurality of semiconductor die 225 of the substrate assembly 200 are respectively disposed within the plurality of openings 306 of the sub-portion 305a. That is the plurality of semiconductor die 225 are exposed (visible, accessible, etc.) through respective openings of the sub-portion 305a, which allows for electrical connections to be made (e.g., with a conductive member, such as the conductive clip 400) to the plurality of semiconductor die 225 in the stacked arrangement of the substrate assembly 200 and the leadframe 300 in FIG. 5.

As further shown in FIG. 5, two semiconductor die of the plurality of semiconductor die 235 of the substrate assembly 200 (the bottom two semiconductor) are respectively disposed within the plurality of openings 311 of the sub-portion 310a. That is the bottom row of semiconductor die of the plurality of semiconductor die 235 are exposed through respective openings of the sub-portion 310a, which allows for electrical to be made connections (e.g., with a conductive member, such as the conductive clip 400) to those in the stacked arrangement of the substrate assembly 200 and the leadframe 300 in FIG. 5. As compared to the arrangement of the plurality of openings 311 in the sub-portion 305a, and the plurality of semiconductor die 225, the plurality of openings 311 of the sub-portion 310a includes two openings 311 corresponding with the bottom row of the plurality of semiconductor die 235. As shown in FIG. 5, semiconductor die included in the top row of the plurality of semiconductor die 235 are coupled with the metal layer 215, but are disposed between the sub-portion 305a and the sub-portion 310a of the leadframe 300, e.g., are not disposed within openings defined through a corresponding portion of the leadframe 300.

FIG. 6A is a diagram illustrating the substrate assembly of FIG. 2, the leadframe 300 of FIG. 3 and conductive clips 400a and 400b (e.g., two of the conductive clips 400 of FIG. 4) in an example stacked arrangement (e.g., vertically stacked arrangement). FIG. 6B is a diagram that illustrates a magnified portion of the diagram of FIG. 6A. In some implementations, the example structure shown in FIGS. 6A and 6B can be a sub-assembly 600 of a semiconductor device module, e.g., the semiconductor device assembly 100.

As compared with the sub-assembly 500 shown in FIG. 5, the sub-assembly 600 shown in FIG. 6A (and in part in FIG. 6B) include a first conductive member (e.g., the conductive clip 400a) that is coupled (e.g., physically and electrically) with the sub-portion 305a of the leadframe 300 and respective contact pads of the plurality of semiconductor die 225. The sub-assembly 600 also include a second conductive member (e.g., the conductive clip 400b) that is coupled (e.g., physically and electrically) with the sub-portion 310a of the leadframe 300 and respective contact pads of the plurality of semiconductor die 235. In some implementations, the conductive clip 400a and the conductive clip 400b can be self-aligned in the sub-assembly 600, e.g., using alignment features of the leadframe 300, such as those described herein. Further in FIG. 6A, the molding compound 130 is shown in transparent outline by way of reference, and so that the structure of the sub-assembly 600 is visible.

Referring to FIG. 6B, a magnified view of the arrangement of the conductive clip 400a in the sub-assembly 600 is shown. As illustrated in FIG. 6B, the plurality of semiconductor die 225 (e.g., high-side transistors) are disposed within respective openings of the plurality of openings 306 of the leadframe 300, such as described above. The portion 405 of the conductive clip 400a is coupled with the surface 308 of the sub-portion 305a of the leadframe 300, where respective portions of the surface 308 border the plurality of openings 306. As shown in FIG. 6B, features of the surface 308, as well as the respective alignment features 307 included in respective sidewalls of the plurality of openings 306 facilitate alignment of the conductive clip 400a in the sub-assembly 600. That is, the respective alignment features 307 and/or features of the surface 308 provided for self-alignment of the portions 410 to 425 of the conductive clip 400a with respective contact pads of the plurality of semiconductor die 225 (e.g., source terminal connections of high side transistors of a half-bridge circuit). In this example, the terminal 105 of the leadframe 300 implements an output (AC) terminal of the half-bridge circuit.

Referring again to FIG. 6A, the conductive clip 400b is coupled (electrically and physically) with the sub-portion 310a (e.g., the surface 313 of the sub-portion 310a) and with respective contact pads of the plurality of semiconductor die 235. As with the conductive clip 400a, the respective alignment features 312 of the sub-portion 310a, and/or features of the surface 313 can provide for self-alignment of the portions 410 to 425 of the conductive clip 400b with respective contact pads of the plurality of semiconductor die 235 (e.g., source terminal connections of low side transistors of a half-bridge circuit).

In this example, the terminal 115 of the leadframe 300 implements a negative power supply terminal (e.g., DC-, electrical ground, etc.) of a half-bridge circuit, and the terminals 110a and 110b implement power supply terminals (DC+, Vcc, etc.) of the half-bridge circuit. The terminal 110a and the terminal 110b are coupled, physically and electrically) with the metal layer 210, which provides electrical connection from the terminal 110a and the terminal 110b to respective drain terminals of the high-side transistors of the half-bridge circuit (e.g., of the plurality of semiconductor die 225). Also in this example, as noted above, the contact tabs 309a of the sub-portion 305a of the leadframe 300 electrically couple the metal layer 215 with the terminal 105 (e.g., electrically coupling respective drain terminals of the plurality of semiconductor die 235 (low-side transistors) with the output terminal of the half-bridge circuit of this example, e.g., the terminal 105.

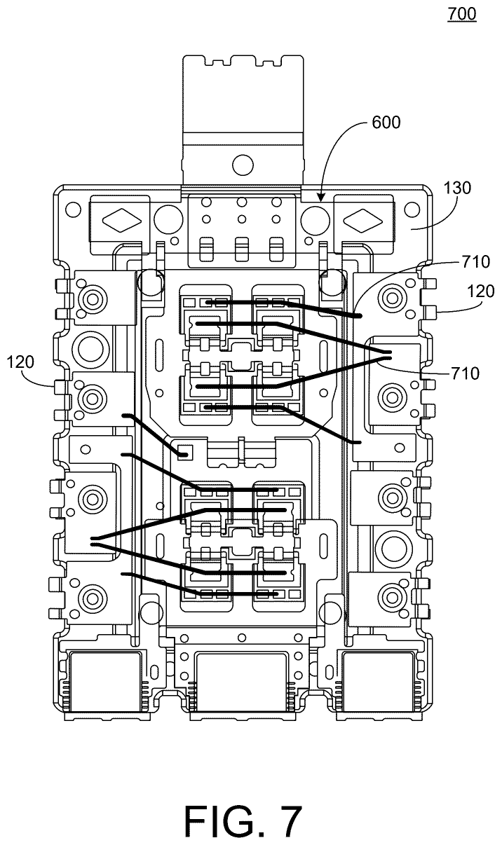

FIG. 7 is a diagram illustrating an example of the stacked arrangement of FIGS. 6A and 6B after adding wire bonds (e.g., attaching bond wires 710). That is, FIG. 7 illustrates a sub-assembly 700 that includes the sub-assembly 600 after formation of wire bonds with bond wires 710. As shown in FIG. 7, the bond wires 710 respectively electrically couple the metal layer 125 of the leadframe 300 with either the plurality of semiconductor die 225, the plurality of semiconductor die 235, the conductive clip 400a, or the conductive clip 400b of the sub-assembly 600. In the half-bridge circuit example, the bond wires 710 implement, at least in part, gate terminal connections for the plurality of semiconductor die 225 and the plurality of semiconductor die 235, and source sense connections for the plurality of semiconductor die 225 and the plurality of semiconductor die 235 (e.g., via the conductive clip 400a and the conductive clip 400b). As with the sub-assembly 600 in FIG. 6A, in FIG. 7, the molding compound 130 is shown in transparent outline by way of reference, and so that the structure of the sub-assembly 700 is visible

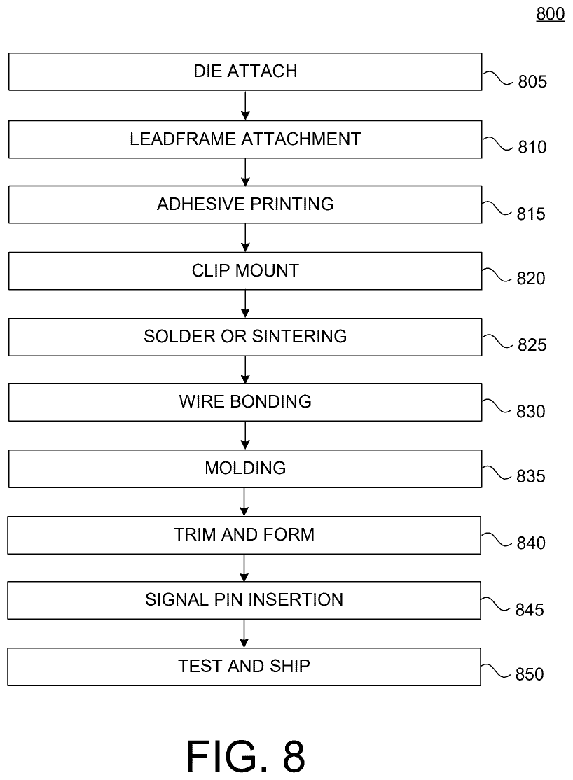

FIG. 8 is a flowchart illustrating an example method 800 for producing a semiconductor device assembly, such as the assembly 100 of FIGS. 1A to 1C (and the various sub-assemblies described herein). Accordingly, for purposes of illustration, the method 800 is described with further reference to FIG. 1A to FIG. 7.

At operation 805, the method includes attaching semiconductor die, e.g., to a substrate. For instance, the operation 805 can include depositing (printing, dispensing, placing, etc.) an adhesive material on the substrate 205 of the substrate assembly 200, e.g., on the metal layer 210 and the metal layer 215. The operation 805 can also include depositing adhesive material for attachment of the temperature sensing device 240 of the substrate assembly 200. After application of the adhesive material, which can be a solder preform, solder paste, a sintering preform, sintering paste, and/or other conductive adhesive material, the plurality of semiconductor die 225, the plurality of semiconductor die 235 and the temperature sensing device 240 can be positioned (placed, etc.) on corresponding portions of the deposited adhesive material. The operation 805 can also include dispensing or depositing conductive adhesive and/or non-conductive adhesive for attachment of the leadframe 300 with the substrate assembly 200.

At operation 810, the method includes attaching the leadframe 300 with the substrate assembly 200, such as in the arrangement shown in FIG. 5. At operation 815, the method 800 includes an adhesive printing operation (or dispensing operation) to apply conductive adhesive for attachment of the conductive clips 400a and 400b to the leadframe 300 (e.g., the surface 308 and the plurality of openings 311) and respective contact pads on the plurality of semiconductor die 225 and the plurality of semiconductor die 235. At operation 820, the method 800 includes attaching the conductive clips 400a and 400b with the sub-assembly 500 of FIG. 5 in correspondence with the conductive adhesive of operation 815, such as in the self-aligned arrangement of FIGS. 6A and 6B. At operation 825, the method includes a soldering and/or sintering operation to couple (physically and electrically) the components of the sub-assembly 600 with each other with the conductive adhesives of operations 805 and 815. In some implementations, operations other than soldering or sintering can be performed, such a cure operation for a conductive epoxy adhesive.

At operation 830, the bond wires 710 are used to form wire bonds, such as in the sub-assembly 700 of FIG. 7. At operation 835, the method 800 includes a molding operation (e.g., transfer molding) to apply the molding compound 130 to the sub-assembly 700 of FIG. 7. At operation 840, the method 800 includes a trim and form operation, which can include removal of tie bars of the leadframe 300 and forming (e.g., bending) of terminals, such as the terminal 105.

At operation 845, the method 800 incudes respectively inserting the signal pins 140 in the plurality of signal pin sockets 325 of the leadframe 300, e.g., where the plurality of signal pin sockets 325 are not encapsulated in the molding compound 130 so as to be accessible for insertion of the signal pins 140. At operation 850, the completed semiconductor device assembly 100 can be functionally tested and then shipped, e.g., to a customer for inclusion a corresponding electrical or electronic system.

In a general aspect, a semiconductor device assembly includes a substrate, a semiconductor die electrically coupled with the substrate, and a leadframe portion having an opening defined therethrough. The leadframe portion is coupled with the substrate such that the semiconductor die is disposed within the opening. The assembly further includes a conductive member having a first portion that is electrically coupled with a surface of the leadframe portion bordering the opening; and a second portion that is electrically coupled with the semiconductor die.

Implementations can include one or more of the following features or aspects, alone or in combination. For example, the semiconductor die can be a first semiconductor die and the opening can be a first opening. The semiconductor device assembly can include a second semiconductor die electrically coupled with the substrate. The leadframe portion can having a second opening defined therethrough. The second semiconductor die can be disposed within the second opening. The conductive member can include a third portion electrically coupled with the second semiconductor die.

A sidewall of the first opening can include a first alignment feature. A sidewall of the second opening can include a second alignment feature. The first alignment feature and the second alignment feature can be configured to facilitate alignment of the second portion of the conductive member with a contact pad of the first semiconductor die and alignment of the third portion of the conductive member with a contact pad of the second semiconductor die.

The assembly can include a third semiconductor die electrically coupled with the substrate, and a fourth semiconductor die electrically coupled with the substrate. The leadframe portion can have a third opening and a fourth opening defined therethrough. The third semiconductor die can be disposed within the third opening. The fourth semiconductor die can be disposed within the fourth opening. The conductive member can include a fourth portion electrically coupled with the third semiconductor die. The conductive member can include a fifth portion electrically coupled with the fourth semiconductor die.

The semiconductor die can be a first semiconductor die, the leadframe portion can be a first leadframe portion, the opening can be a first opening, and the conductive member can be a first conductive member. The assembly can include a second semiconductor die electrically coupled with the substrate, and a second leadframe portion having a second opening defined therethrough. The second leadframe portion can be coupled with the substrate such that the second semiconductor die is disposed within the second opening. The second conductive member can include a first portion electrically coupled with a surface of the second leadframe portion bordering the second opening, and a second portion electrically coupled with the second semiconductor die.

The assembly can include a third semiconductor die electrically coupled with the substrate. The third semiconductor die can be disposed between the first leadframe portion and the second leadframe portion. The second conductive member can include a third portion electrically coupled with the third semiconductor die.

The first conductive member can be a first conductive clip. The second conductive member can be a second conductive clip.

The semiconductor device assembly can include a third semiconductor die electrically coupled with the substrate, and a fourth semiconductor die electrically coupled with the substrate. The first leadframe portion can have a third opening defined therethrough. The third semiconductor die can be disposed within the third opening. The first conductive member can include a third portion electrically coupled with the third semiconductor die. The second leadframe portion can have a fourth opening defined therethrough. The fourth semiconductor die can be disposed within the fourth opening. The second conductive member can include a third portion electrically coupled with the fourth semiconductor die.

The substrate can be a direct-bonded metal (DBM) substrate including a first patterned metal layer disposed on a surface of the DBM substrate, and a second patterned metal layer disposed on the surface. The first semiconductor die can be electrically coupled with the first patterned metal layer. The second semiconductor die and the first leadframe portion can be electrically coupled with the second patterned metal layer.

The first leadframe portion can be electrically isolated from the first patterned metal layer. The second leadframe portion can be electrically isolated from the first patterned metal layer and the second patterned metal layer.

The first leadframe portion can include an output signal terminal. The second leadframe portion can include a power supply terminal. The power supply terminal can be a first power supply terminal. The semiconductor assembly can further include a second power supply terminal electrically coupled with the first patterned metal layer.

The assembly can include a first signal terminal that is electrically coupled with the semiconductor die by a first electrical connector, and a second signal terminal that is coupled with the conductive member by a second electrical connector. The first electrical connector can be a first bond wire. The second electrical connector can be a second bond wire.

The assembly can include a thermal sensor, and a third signal terminal that is coupled with the thermal sensor by a third electrical connector.

In another general aspect, a semiconductor device assembly includes a substrate, a first semiconductor die, a second semiconductor die, a third semiconductor die and a fourth semiconductor die electrically coupled with the substrate. The assembly further includes a first leadframe portion having a first opening and a second opening defined therethrough. The first leadframe portion is coupled with the substrate such that the first semiconductor die is disposed within the first opening and the second semiconductor die is disposed within the second opening. The assembly further includes a first conductive member having a first portion electrically coupled with a surface of the first leadframe portion bordering the first opening and the second opening, a second portion electrically coupled with the first semiconductor die, and a third portion electrically coupled with the second semiconductor die. The assembly also includes a second leadframe portion having a third opening and a fourth opening defined therethrough. The second leadframe portion is coupled with the substrate such that the third semiconductor die is disposed within the third opening, and the fourth semiconductor die is disposed within the fourth opening. The assembly also includes a second conductive member having a first portion electrically coupled with a surface of the second leadframe portion bordering the third opening and the fourth opening, a second portion electrically coupled with the third semiconductor die, and a third portion electrically coupled with the fourth semiconductor die.

Implementations can include one or more of the following features or aspects, alone or in combination. For example, a sidewall of the first opening can include a first alignment feature, and a sidewall of the second opening can include a second alignment feature. A sidewall of the third opening can include a third alignment feature; and a sidewall of the fourth opening includes a fourth alignment feature. The first alignment feature and the second alignment feature can be configured to facilitate alignment of the second portion of the first conductive member with a contact pad of the first semiconductor die and alignment of the third portion of the first conductive member with a contact pad of the second semiconductor die. The third alignment feature and the fourth alignment feature can be configured to facilitate alignment of the second portion of the second conductive member with a contact pad of the third semiconductor die and alignment of the third portion of the second conductive member with a contact pad of the fourth semiconductor die.

The substrate can include a first patterned metal layer disposed on a surface of the substrate, and a second patterned metal layer disposed on the surface. The first semiconductor die and the second semiconductor die can be electrically coupled with the first patterned metal layer. The third semiconductor die, the fourth semiconductor die and the first leadframe portion can being electrically coupled with the second patterned metal layer.

In another general aspect, a method for producing a semiconductor device assembly includes electrically coupling a semiconductor die with a substrate. The method further includes coupling a leadframe portion with the substrate such that the semiconductor die is disposed within an opening defined in the leadframe portion. The method also includes coupling a conductive member with the semiconductor die and the leadframe portion such that a first portion of the conductive member is electrically coupled with a surface of the leadframe portion bordering the opening and a second portion of the conductive member is electrically coupled with a contact pad of the semiconductor die.

Implementations can include one or more of the following features or aspects, alone or in combination. For example, the semiconductor die is a first semiconductor die, the leadframe portion is a first leadframe portion, the opening is a first opening and the conductive member is a first conductive member, the method further including: electrically coupling a second semiconductor die with the substrate; coupling a second leadframe portion with the substrate such that the second semiconductor die is disposed within a second opening defined in the second leadframe portion; and coupling a second conductive member with the second semiconductor die and the second leadframe portion such that a first portion of the second conductive member is electrically coupled with a surface of the second leadframe portion bordering the second opening and a second portion of the second conductive member is electrically coupled with a contact pad of the second semiconductor die.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly comprising:
a substrate;
a semiconductor die electrically coupled with the substrate;
a leadframe portion having an opening defined therethrough, the leadframe portion being coupled with the substrate such that the semiconductor die is disposed within the opening; and
a conductive member including:
a first portion electrically coupled with a surface of the leadframe portion bordering the opening; and
a second portion electrically coupled with the semiconductor die.

2. The semiconductor device assembly of claim 1, wherein the semiconductor die is a first semiconductor die and the opening is a first opening, the semiconductor device assembly further comprising a second semiconductor die electrically coupled with the substrate,
the leadframe portion having a second opening defined therethrough,
the second semiconductor die being disposed within the second opening, and
the conductive member including a third portion electrically coupled with the second semiconductor die.

3. The semiconductor device assembly of claim 2, wherein:
a sidewall of the first opening includes a first alignment feature; and
a sidewall of the second opening includes a second alignment feature,
the first alignment feature and the second alignment feature being configured to facilitate alignment of the second portion of the conductive member with a contact pad of the first semiconductor die and alignment of the third portion of the conductive member with a contact pad of the second semiconductor die.

4. The semiconductor device assembly of claim 2, further comprising:
a third semiconductor die electrically coupled with the substrate; and
a fourth semiconductor die electrically coupled with the substrate,
the leadframe portion having a third opening and a fourth opening defined therethrough,
the third semiconductor die being disposed within the third opening,
the fourth semiconductor die being disposed within the fourth opening,
the conductive member including a fourth portion electrically coupled with the third semiconductor die, and
the conductive member including a fifth portion electrically coupled with the fourth semiconductor die.

5. The semiconductor device assembly of claim 1, wherein the semiconductor die is a first semiconductor die, the leadframe portion is a first leadframe portion, the opening is a first opening and the conductive member is a first conductive member, the semiconductor device assembly further comprising:
a second semiconductor die electrically coupled with the substrate;
a second leadframe portion having a second opening defined therethrough, the second leadframe portion being coupled with the substrate such that the second semiconductor die is disposed within the second opening; and
a second conductive member including:
a first portion electrically coupled with a surface of the second leadframe portion bordering the second opening; and
a second portion electrically coupled with the second semiconductor die.

6. The semiconductor device assembly of claim 5, further comprising a third semiconductor die electrically coupled with the substrate,
the third semiconductor die being disposed between the first leadframe portion and the second leadframe portion, and
the second conductive member further including a third portion electrically coupled with the third semiconductor die.

7. The semiconductor device assembly of claim 5, wherein:
the first conductive member is a first conductive clip; and
the second conductive member is a second conductive clip.

8. The semiconductor device assembly of claim 5, further comprising:
a third semiconductor die electrically coupled with the substrate; and
a fourth semiconductor die electrically coupled with the substrate,
the first leadframe portion having a third opening defined therethrough, the third semiconductor die being disposed within the third opening,
the first conductive member including a third portion electrically coupled with the third semiconductor die,
the second leadframe portion having a fourth opening defined therethrough, the fourth semiconductor die being disposed within the fourth opening, and
the second conductive member including a third portion electrically coupled with the fourth semiconductor die.

9. The semiconductor device assembly of claim 5, wherein the substrate is a direct-bonded metal (DBM) substrate including:
a first patterned metal layer disposed on a surface of the DBM substrate; and
a second patterned metal layer disposed on the surface,
the first semiconductor die being electrically coupled with the first patterned metal layer, and
the second semiconductor die and the first leadframe portion being electrically coupled with the second patterned metal layer.

10. The semiconductor device assembly of claim 9, wherein:
the first leadframe portion is electrically isolated from the first patterned metal layer; and
the second leadframe portion is electrically isolated from the first patterned metal layer and the second patterned metal layer.

11. The semiconductor device assembly of claim 9, wherein:
the first leadframe portion includes an output signal terminal; and
the second leadframe portion includes a power supply terminal.

12. The semiconductor device assembly of claim 11, wherein the power supply terminal is a first power supply terminal, the semiconductor device assembly further comprising:
a second power supply terminal electrically coupled with the first patterned metal layer.

13. The semiconductor device assembly of claim 1, further comprising:
a first signal terminal that is coupled with the semiconductor die by a first electrical connector; and
a second signal terminal that is coupled with the conductive member by a second electrical connector.

14. The semiconductor device assembly of claim 13, wherein:
the first electrical connector is a first bond wire; and
the second electrical connector is a second bond wire.

15. The semiconductor device assembly of claim 13, further comprising:
a thermal sensor; and
a third signal terminal that is coupled with the thermal sensor by a third electrical connector.

16. A semiconductor device assembly comprising:
a substrate;
a first semiconductor die, a second semiconductor die, a third semiconductor die and a fourth semiconductor die electrically coupled with the substrate;
a first leadframe portion having a first opening and a second opening defined therethrough, the first leadframe portion being coupled with the substrate such that the first semiconductor die is disposed within the first opening and the second semiconductor die is disposed within the second opening;
a first conductive member including:
a first portion electrically coupled with a surface of the first leadframe portion bordering the first opening and the second opening;
a second portion electrically coupled with the first semiconductor die; and
a third portion electrically coupled with the second semiconductor die;
a second leadframe portion having a third opening and a fourth opening defined therethrough, the second leadframe portion being coupled with the substrate such that the third semiconductor die is disposed within the third opening and the fourth semiconductor die is disposed within the fourth opening; and
a second conductive member including:
a first portion electrically coupled with a surface of the second leadframe portion bordering the third opening and the fourth opening;
a second portion electrically coupled with the third semiconductor die; and
a third portion electrically coupled with the fourth semiconductor die.

17. The semiconductor device assembly of claim 16, wherein:
a sidewall of the first opening includes a first alignment feature;
a sidewall of the second opening includes a second alignment feature;
a sidewall of the third opening includes a third alignment feature; and
a sidewall of the fourth opening includes a fourth alignment feature,
the first alignment feature and the second alignment feature being configured to facilitate alignment of the second portion of the first conductive member with a contact pad of the first semiconductor die and alignment of the third portion of the first conductive member with a contact pad of the second semiconductor die, and
the third alignment feature and the fourth alignment feature being configured to facilitate alignment of the second portion of the second conductive member with a contact pad of the third semiconductor die and alignment of the third portion of the second conductive member with a contact pad of the fourth semiconductor die.

18. The semiconductor device assembly of claim 16, wherein the substrate includes:
a first patterned metal layer disposed on a surface of the substrate; and
a second patterned metal layer disposed on the surface,
the first semiconductor die and the second semiconductor die being electrically coupled with the first patterned metal layer, and
the third semiconductor die, the fourth semiconductor die and the first leadframe portion being electrically coupled with the second patterned metal layer.

19. A method for producing a semiconductor device assembly, the method comprising:
electrically coupling a semiconductor die with a substrate;
coupling a leadframe portion with the substrate such that the semiconductor die is disposed within an opening defined in the leadframe portion; and
coupling a conductive member with the semiconductor die and the leadframe portion such that a first portion of the conductive member is electrically coupled with a surface of the leadframe portion bordering the opening and a second portion of the conductive member is electrically coupled with a contact pad of the semiconductor die.

20. The method of claim 19, wherein the semiconductor die is a first semiconductor die, the leadframe portion is a first leadframe portion, the opening is a first opening and the conductive member is a first conductive member, the method further comprising:
electrically coupling a second semiconductor die with the substrate;
coupling a second leadframe portion with the substrate such that the second semiconductor die is disposed within a second opening defined in the second leadframe portion; and
coupling a second conductive member with the second semiconductor die and the second leadframe portion such that a first portion of the second conductive member is electrically coupled with a surface of the second leadframe portion bordering the second opening and a second portion of the second conductive member is electrically coupled with a contact pad of the second semiconductor die.
